(19) United States
(12) Patent Application Publication
(10) Pub. No.: US 2025/0234574 A1
(43) Pub. Date: Jul. 17, 2025

(54) METHOD FOR MANUFACTURING A 3D CIRCUIT WITH SHARED RECRYSTALLISATION AND DOPANT ACTIVATION STEPS

(71) Applicants: COMMISSARIAT A L'ENERGIE ATOMIQUE ET AUX ENERGIES ALTERNATIVES, Paris (FR); SOITEC, Bernin (FR)

(72) Inventors: Shay REBOH, Grenoble Cedex 09 (FR); Gweltaz GAUDIN, Bernin (FR)

(73) Assignees: COMMISSARIAT A L'ENERGIE ATOMIQUE ET AUX ENERGIES ALTERNATIVES, Paris (FR); SOITEC, Bernin (FR)

(21) Appl. No.: 18/716,376

(22) PCT Filed: Dec. 5, 2022
(86) PCT No.: PCT/FR2022/052242

§ 371 Date: Jun. 4, 2024

(30) Foreign Application Priority Data
Dec. 6, 2021 (FR) FR2112982

(51) Int. Cl. H10D 30/01; H10D 62/40; H10D 88/00

(52) U.S. Cl. CPC H10D 30/0227; H10D 30/027; H10D 62/402; H10D 88/01

(57) ABSTRACT

A method for fabricating a microelectronic device includes: producing a structure with a support provided with a semiconductor layer of a first level of components and another semiconductor layer of a second level, the other semiconductor layer including a lower sublayer contacting the insulating layer and an upper sublayer disposed on the lower sublayer, one of the lower and upper sublayers made from crystalline material while another of the lower and upper sublayers made from amorphous material; forming a transistor gate block on the semiconductor layer; forming, on either side of the gate block, by implanting dopants in the semiconductor layer, doped regions on either side of a semiconductor region facing the gate block for accommodating a channel of the transistor; and implementing heat treatment to recrystallize the second semiconductor sublayer while using the first semiconductor sublayer as a start region of a crystalline front while activating the dopants.

### TECHNICAL FIELD AND PRIOR ART

The present application relates to the field of microelectronic devices and in particular that of devices provided with components distributed over a plurality of levels. Such devices are generally termed 3-dimensional or “3D” integrated circuits.

In general, in the field of integrated circuits, it is continually sought to increase the density of transistors.

For this purpose, one solution consists in distributing the transistors over a plurality of levels of semiconductor layers disposed one above the other. Such circuits thus generally include at least two superimposed semiconductor layers, with an insulating layer interposed between these two semiconductor layers.

The document of Brunet et al. “First demonstration of a CMOS over CMOS 3D VLSI CoolCube™ integration on 300 mm wafer”, 2016 Symposium on VLSI Technology Digest of Technical Papers presents for example a use of such a type of device.

Producing transistors on the upper level may involve implementing one or more heat treatment steps, in particular when an activation of the dopants is implemented.

However, a high-temperature heat treatment may cause degradation of the lower level or levels and in particular damage to the material of the contacts in the lower level or of interlevel connection elements or even an unwanted diffusion of dopants within the lower level.

Once the first level of transistors has been produced, it is therefore generally sought to limit the thermal budget of manufacture of the upper level or levels and in particular to avoid implementing heat treatments above 600° C.

Activation of the dopants or furthermore diffusion of the dopants to create the extension regions is one of the most critical problems when it is wished to produce transistors in an upper level of the 3D circuit. Such a step generally requires a high temperature that may be greater than 1000° C.

A method illustrated on FIGS. 9A-9B, used for 2D devices and thus including a single level of transistors, consists in making amorphous and doping by means of implantations semiconductor regions 925 on either side of a gate block 932 on which spacers 932 are arranged.

During recrystallisation, horizontal F_{H} and vertical F_{V} recrystallisation fronts are liable to be created, which may cause a creation of crystalline defects at a point where the fronts F_{H} and F_{V} meet.

Such a method is typically implemented on an SOI substrate (SOI standing for “Silicon On Insulator”) and controlling the thickness end of a non-doped layer 926 under the regions 925, regions made amorphous and doped and then recrystallised, poses a problem. This is because this non-doped layer 926 is liable to contribute to increasing the resistance to access and to an impact on the performances of the device.

Furthermore, for very thin semiconductor layers, for example intended for applications of the FDSOI type (standing for “Fully Depleted Silicon On Insulator”), it may be difficult, if an excessively deep amorphising implantation is implemented, to preserve a thickness of crystal nucleus for recrystallisation. This is moreover particularly difficult and critical if the amorphisation is implemented after an epitaxial growth of the source and drain regions since, in this case, the semiconductor thickness varies along the support of this layer.

The problem is posed of finding a novel method for manufacturing a 3D microelectronic device that is improved with regard to at least one of the drawbacks stated above.

### DESCRIPTION OF THE INVENTION

According to one aspect, the present invention relates to a method for producing a microelectronic device provided with a plurality of superimposed levels of electronic components, the method comprising, in this order, steps consisting in:
a) producing a structure comprising a support provided with at least one component of a first level N₁ of components, said support being surmounted by an insulating layer, the insulating layer itself being surmounted by a semiconductor layer of a second level,
said semiconductor layer including at least one lower sublayer and an upper sublayer disposed on the lower sublayer, a first of said lower and upper sublayers being made from crystalline semiconductor material while a second of said lower and upper sublayers is made from amorphous semiconductor material, then
b) forming at least one transistor gate block on said semiconductor layer, then
c) forming, on either side of the gate block, by implantation(s) of dopants in said semiconductor layer, doped regions on either side of a semiconductor region located facing the gate block and provided for accommodating a channel of said transistor, then
d) implementing at least one heat treatment so as to implement a recrystallisation of the second amorphous sublayer while using the first crystalline sublayer as a start region of a crystalline front while implementing an activation of said dopants.

The step a) may comprise an amorphisation implantation of a thickness of said semiconductor layer of the second level N₂ so as to form said second sublayer made from amorphous semiconductor material.

Advantageously, said second sublayer made from amorphous semiconductor material extends over the entire surface so that the support is entirely covered by the second sublayer.

According to a first possibility of implementation, at the step a), the first sublayer, made from amorphous material, is the upper sublayer, said second sublayer, made from crystalline material, being the lower sublayer.

In a variant and according to a second possibility of implementation, at the step a), the first sublayer, which is amorphous, is the lower sublayer, said second sublayer, which is crystalline, being the surface sublayer.

Advantageously, the formation of the structure at the step a) may comprise substeps consisting in:
providing a first substrate wherein said at least one component of said first level N₁ of components is produced,
bonding, on the first substrate, a second substrate provided with said semiconductor layer of said second level,
removing a portion of the second substrate while preserving the second semiconductor layer bonded to the first substrate.

When the removal of said portion is implemented by fracturing and/or by means of a method of the Smart Cut™ type, the heat treatment step d) can make it possible to implement a repair of defects liable to have been generated by this fracturing.

According to a particular embodiment, the step a) may furthermore comprise, prior to said bonding, a step of amorphisation of said semiconductor layer of the second level so as to form the second semiconductor sublayer.

The amorphisation of said semiconductor layer can in a variant be implemented after said creation of said weakening region.

Implementing this step before bonding makes it possible best to control the respective thicknesses of the first sublayer and of the second sublayer.

Advantageously, when, prior to said bonding, an implantation of the first substrate is implemented so as to create a weakening region, the amorphisation of said semiconductor layer can be implemented after said creation of said weakening region.

Advantageously, an etching stop layer is arranged on the second substrate and up against said semiconductor layer, the removal of a portion of the second substrate furthermore comprising a selective etching of the etching stop layer with respect to said semiconductor layer.

The method may further comprise the formation of insulating spacers on either side of the gate block.

In this case, the step c) of forming the doped regions may then comprise an implantation of dopants before said formation of the insulating spacers, or
the step c) of forming the doped regions may comprise an implantation of dopants implemented after said formation of the insulating spacers and, advantageously, said implantation of dopants being implemented in a way that is inclined with respect to a normal to the principal plane of the semiconductor layer.

Advantageously, the method may furthermore comprise, after the heat treatment step d), at least one supplementary implantation of dopants.

According to one possibility of implementation, the method may furthermore comprise, after the step d): a growth of semiconductor blocks on either side of the gate block on the semiconductor layer.

According to one possibility of implementation of the method wherein, at the step a), the first sublayer, which is amorphous, is the lower sublayer, while said second sublayer, which is crystalline, is the surface sublayer, the method may furthermore comprise, after the step d) and prior to the growth of said semiconductor blocks, the removal of non-doped surface regions.

Advantageously, the recrystallisation is a solid-phase recrystallisation, the heat treatment being implemented at a temperature of below 550° C., advantageously below 500° C., typically between 450° C. and 500° C.

Advantageously, the first component level is produced at least partly in a layer of semiconductor material.

### BRIEF DESCRIPTION OF THE DRAWINGS

The invention will be best understood from the reading of the description of example embodiments given, purely by way of indication and in no way limitatively, with reference to the accompanying drawings, on which:

FIGS. 1A, 1B, 1C, 1D, 1E, 1F serve to illustrate a first example of a method, according to the invention, for producing a 3D integrated circuit with an upper level provided with transistor(s);

FIG. 2 serves to illustrate an example of a structure provided with at least one level of components whereon the upper level of transistor(s) can be formed;

FIG. 3 serves to illustrate an example of a step of doping by inclined implantation able to be implemented during a method according to the invention;

FIG. 4 serves to illustrate an example of a step of doping by implantation before forming spacers and able to be implemented during a method according to the invention;

FIGS. 5A, 5B serve to illustrate serves to illustrate an example of a step of doping by implantation before forming spacers and after forming regions protecting the gate and able to be implemented during a method according to the invention;

FIGS. 6A, 6B, 6C, 6D, 6E serve to illustrate a second example of a method according to the invention for producing a 3D integrated circuit with an upper level provided with transistor(s);

FIGS. 7A, 7B, 7C, 7D, 7E serve to illustrate a first sequence of steps of a method for assembling the semiconductor layer of a first level of components and of the semiconductor layer of a second level of components;

FIGS. 8A, 8B, 8C serve to illustrate a second sequence of steps wherein the semiconductor layer of a first level of components and the semiconductor layer of a second set of components are assembled and wherein an amorphisation of the semiconductor layer of the second level is implemented prior to this assembly;

FIGS. 9A, 9B serve to illustrate an example of a method according to the prior art implemented on a device with a single level of transistors.

Identical, similar or equivalent parts of the various figures bear the same numerical references so as to facilitate passing from one figure to another.

The various parts shown on the figures are not necessarily shown to a uniform scale, to make the figures more legible.

Furthermore, in the following description, terms that are dependent on the orientation of the structure such as “upper”, “surface”, “lateral” apply by considering that the structure is oriented as illustrated in the figures.

### DETAILED DESCRIPTION OF PARTICULAR EMBODIMENTS

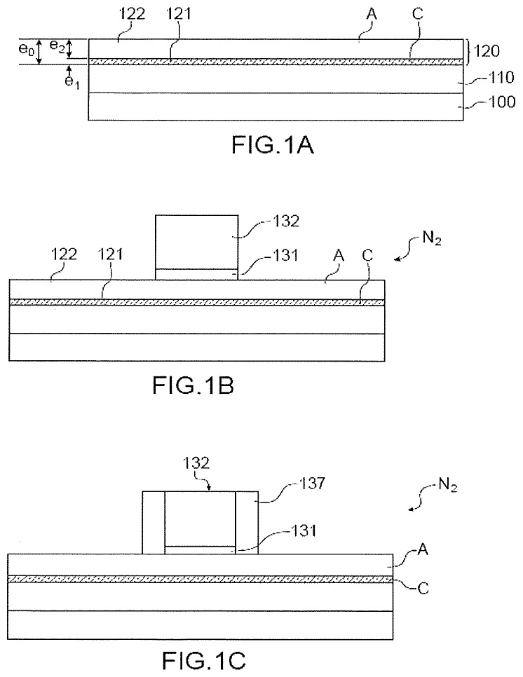

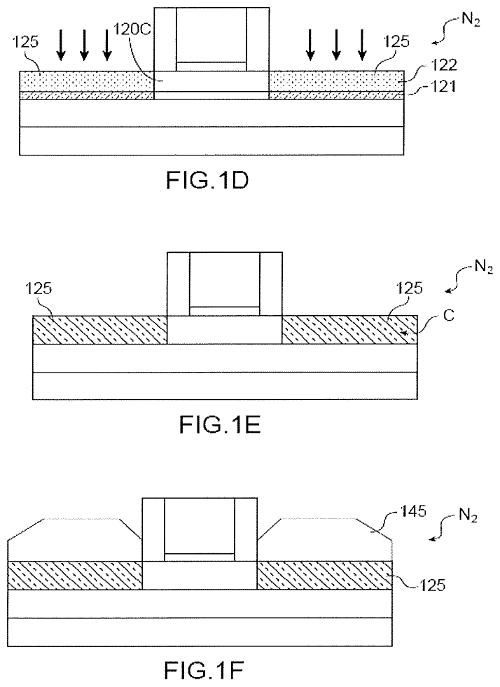

A first example of a method, according to the invention, for producing a microelectronic device provided with one or more transistors will now be described in relation to FIGS. 1A-1F.

A possible starting structure for implementing this method is given on FIG. 1A, this structure comprising a support 100, coated with an insulating layer 110, for example made from SiO₂, the insulating layer 110 itself being coated with a surface semiconductor layer 120 wherein one or more transistors are intended to be formed. The surface semiconductor layer 120, for example made from silicon, may have a thickness e₀ between for example 5 nm and 60 nm.

The semiconductor layer 120 is here delimited in a lower sublayer 121 in contact with said insulating layer 110 and an upper sublayer 122 located on the lower sublayer and which is superficial.

One of said sublayers 121, 122, here the upper sublayer 122, is made from amorphous semiconductor material A while the other of said sublayers 121, 122 is made from crystalline semiconductor material C. In this case, the upper sublayer 122 made from amorphous material A can be provided with a thickness e₂ for example between 3 and 50 nm. The sublayer 121 made from crystalline material C for its part can be provided with a thickness e₁ for example between 2 and 30 nm, for example of the order of 2 or 3 nm.

Advantageously, the upper sublayer 122 made from amorphous material A is produced over the entire surface, the insulating layer 110 and the support 100 thus being able to be opposite the upper sublayer 122 over the entire extent thereof (taken parallel to a plane [O; x; y] of an orthogonal reference frame [O; x; y; z]). The upper sublayer 122 made from amorphous material A is typically formed by means of one or more amorphisation implantations.

Implementing the amorphization, over the entire surface, of a thickness of the semiconductor layer 120 before even forming the transistors (and in particular producing the gates thereof) next makes it possible, when this thickness is recrystallised, to limit the appearance of crystalline defects resulting from recrystallisation fronts in different directions.

The implantation dose and energy are designed so as to achieve an amorphisation while preserving the sublayer 121 in crystalline form. For example, an implantation of Ge+ ions, with dose and energy conditions determined by simulation and experimental verification by TEM (transmission electron microscopy) imaging can be implemented to make a given thickness of a layer of silicon amorphous.

Simulation tools based on a Monte Carlo method, in particular of the TRIM type (TRIM standing for “TRansport of Ions in Matter”) and/or KMC (standing for “Kinetic Monte Carlo”).

The species used for implementing this amorphisation may be a neutral species such as for example Si or Ge.

For example, an implantation of Ge+ ions of 2*10¹⁵ ions*cm⁻² at an energy of 1 keV can make it possible to obtain an amorphous thickness of between 4 and 5 nm, while an implantation of Ge+ ions of 2*10¹⁵ at an energy of 2.5 keV can make it possible to obtain an amorphous thickness of between 7 nm and 10 nm. An implantation of Ge+ ions of 2*10¹⁵ at an energy of 3.5 keV can make it possible to obtain an amorphous thickness of between 10 and 12 nm.

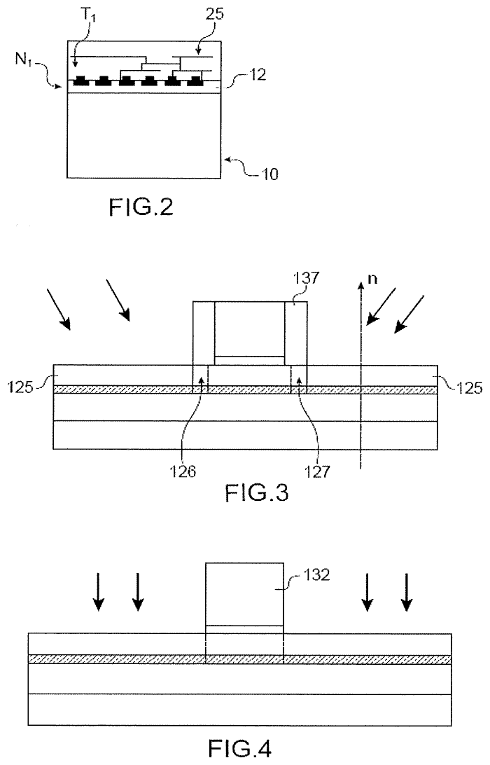

In this particular example embodiment, the support 100 on which the semiconductor layer 120 is disposed can be formed from a structure provided with a first substrate 10 and a semiconductor layer 12 wherein one or more components, in particular electronic components, have already been formed. The first substrate 10 may be a solid substrate (“bulk” according to English terminology) or a substrate of the semiconductor on insulator type, in particular SOI, on which a semiconductor layer 12 rests. In the particular example embodiment illustrated on FIG. 2, one or more transistors T₁ of a first level N₁ of components implemented in this semiconductor layer 12, their channel region being in particular provided on this layer. The transistors T₁ are here covered with one or more stages of metal interconnections 25 formed in one or more insulating layers, typically a stack of insulating layers, for example made from SiO₂.

The amorphisation of the semiconductor layer 120 may optionally be implemented before a step of assembly between the structure illustrated on FIG. 2 and a stack or another substrate comprising the semiconductor layer 120. Providing an amorphisation of the semiconductor layer 120 before the assembly makes it possible in particular to more easily adjust the respective thicknesses of crystalline material C and amorphous material A.

From the structure in FIG. 1A, one or more transistors of a level N₂ of components are next formed at least partly in the semiconductor layer 120. It is thus a case of producing a device of the type commonly called “3D” and which includes a superimposition of a plurality of semiconductor layers in each of which a component level of a superimposition of components is formed.

Thus, in a step subsequent to the amorphisation of a thickness of the semiconductor layer 120 as well as the optional assembly of this semiconductor layer 120 on the substrate 10 provided with the semiconductor layer 12, a gate stack on the semiconductor layer 120 is formed.

This stack includes at least one gate dielectric layer, for example made from SiO₂ or HfO₂, and one or more layers of gate material, for example based on polysilicon or TiN or W, or a stack of at least a plurality of these materials. Then (FIG. 1B) in this stack a gate dielectric region 131 surmounted by a gate block 132 is defined.

Preferably, a method at a temperature below 500° C. is favoured for producing the gate. In this case and according to a particular example of implementation, the gate dielectric region 131 may be a region of silicon oxide obtained by oxidation of silicon by means of a plasma at a temperature of the order of 450° C. As for the gate material this may be TiN deposited at 350° C. or doped Si deposited at a temperature of the order of 475° C. and which is recrystallised afterwards by means of a laser annealing treatment.

Then (FIG. 1C), spacers 137 are formed on either side of the gate block 132. These spacers 137 may for example be based on SiN or SiBCN or SiOCN. Preferably, there again, a method for implementation at a temperature below 500° C. is favoured. For this purpose it is possible for example to form the spacers 137 by depositing SiCO at a temperature for example of the order of 400° C.

Next doped regions 125 are formed in the semiconductor layer 120, on either side of a region 120C of this layer 120 that is located opposite the gate block 132 and designed to accommodate a transistor channel. These doped regions 125 are typically produced by implanting dopants in the second semiconductor layer 120.

In the example embodiment illustrated on FIG. 1D, the doped regions 125 extend in the amorphous upper sublayer 122 and in the crystalline lower sublayer 121. The implantation conditions can be designed by a person skilled in the art with an implantation simulation tool, of the CTRIM or KMC type as mentioned above.

Preferably, a method for implantation at a temperature below 500° C. is favoured. The implantation method is here mainly implemented at ambient temperature.

Once the implantation of dopants has been implemented, at least one heat treatment is implemented so as to implement recrystallisation annealing of the upper sublayer 122 (FIG. 1E). Use is then made of the lower sublayer 121 as a starting region for a recrystallisation front, this recrystallisation front being in this example a rising front, i.e. moving away from the insulating layer 101.

A method of solid phase epitaxial regrowth (SPER) of the amorphous semiconductor material in contact with the crystalline semiconductor material is in particular implemented at a temperature typically below 600° C., preferably below 500° C., and which may for example be between 450° C. and 500° C. Concomitantly, the heat treatment implemented makes it possible to implement an activation of the dopants. The speed of the SPER recrystallisation method varies according to the temperature, the material, the concentration of dopants and the type of dopants (implanted species). A person skilled in the art will be able to establish the recrystallisation conditions by means of measurements of recrystallised thickness according to the annealing time, the thicknesses being measured for example by ellipsometry. The doped regions 125 are then made from crystalline semiconductor material C. In this way the recrystallisation and activation of the dopants is mutualised while using a limited thermal budget.

In a case where the formation of the support 100 was implemented by transfer and assembly of the semiconductor 120 on a structure provided with another semiconductor layer 12, implementing in particular a method for the Smart Cut™ type, with a fracturing step, the thermal annealing implemented by the aforementioned SPER technique can optionally make it possible to repair crystalline defects liable to have been caused in the semiconductor layer 120 during this fracturing.

The method for producing the transistor or transistors of upper level N₂ can next be continued by implementing a growth of semiconductor blocks 145 on the doped regions 125 and located on either side of the gate block 132 on the semiconductor layer 120. Such a growth can be implemented by epitaxy with an in situ doping step during which a growth of semiconductor material and a doping of this material are mutualised.

The formation of transistor source and drain regions is thus completed (FIG. 1F).

It is then possible to complete the formation of the transistor or transistors by other steps, in particular by forming regions of metal and semiconductor alloy, in particular by implementing a siliciding of the semiconductor regions 145. Such regions make it possible to form contacts and are produced typically by depositing material, for example tungsten or copper, and then annealing.

In a variant of the example of a method that has just been described, it is possible to make provision, in addition to a doping of regions 125 of the semiconductor layer 120 located on either side of the gate 132, for doping so-called extension regions 126 that are located under the spacers 137.

In this case, if the spacers 137 were formed before implementing the doping of the semiconductor layer 120, it is possible to make provision, as on FIG. 3, for implementing an implantation inclined with respect to a normal n to a principal plane of the semiconductor layer 120. In this way it is possible to reach and dope these extension regions 126.

Another possibility for producing these doped extension regions 126 consists in implementing a doping by implantation and as illustrated in FIG. 4, this time before forming the spacers 137. In this case, the implantation conditions, in particular in terms of orientation of the beam, are designed so as to avoid doping under the gate 132.

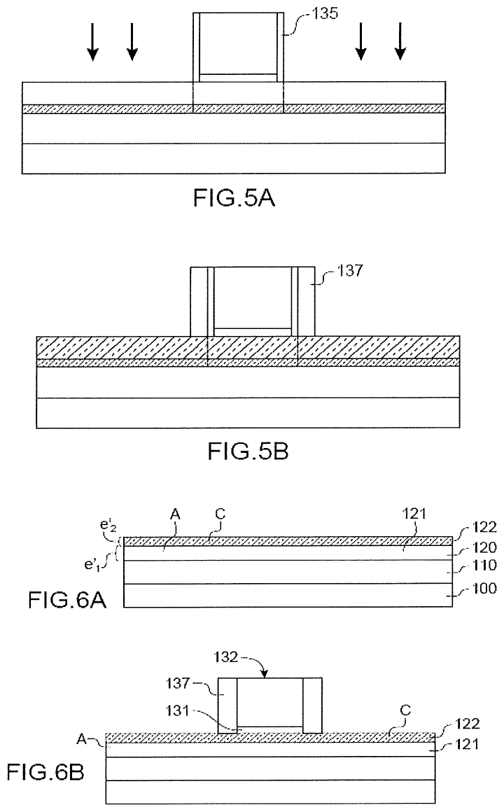

To avoid any doping under the gate 132, it is also possible first to make provision for coating the lateral flanks of the gate block 132 with a fine protective layer 135 made from dielectric material. For example, the fine protective layer 135 is a layer based on a layer of nitride with a thickness of the order of 1 to 10 nm that is etched anisotropically. Then, as on FIG. 5A, one or more implantations are implemented in order to implement a doping. Then (FIG. 5B) the spacers 137 are formed with a greater thickness against the fine protective layer 135. Other implantations can then be implemented if necessary.

According to another variant embodiment, it is possible to provide a reverse order of the amorphous and crystalline thicknesses in the semiconductor layer 120 on which the transistor or transistors are formed.

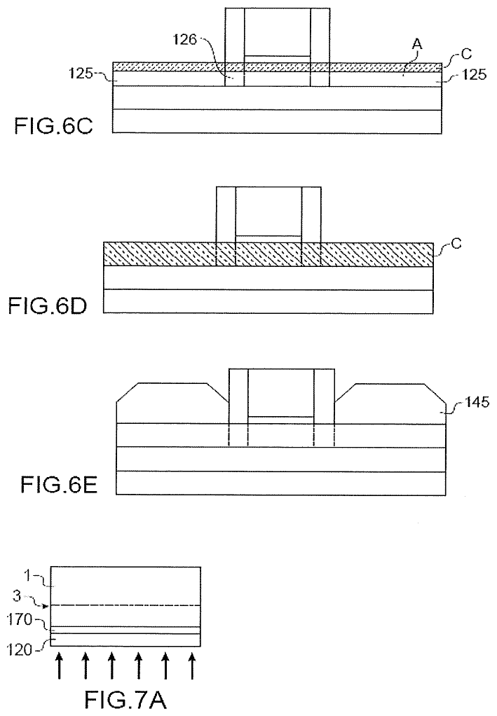

Thus, in the example of a method given on FIGS. 6A-6E, the semiconductor layer 120 this time includes a lower sublayer 121 made from amorphous semiconductor material A, for example amorphous silicon, while the upper sublayer 122 is made from crystalline material C, for example crystalline silicon.

To obtain a structure as illustrated on FIG. 6A, typically the implementation of the amorphisation, in particular by implantation(s), is privileged before implementing a method, as mentioned previously, for assembly between a structure for example as illustrated on FIG. 2 and including a semiconductor layer 12 with a first level of components and another structure or another substrate provided with the second semiconductor layer 120.

It can thus be easier to obtain a completely amorphous sublayer 121 and in particular in proximity to the insulating layer 110 rather than when it is wished to implement the amorphisation implantation or implantations once the semiconductor layer 120 and the insulating layer 110 are assembled and adhesively bonded to each other.

The lower sublayer 121 made from amorphous material A can be provided with a thickness e′₁ for example between 3 nm and 50 nm. The upper sublayer 122 made from crystalline material C for its part can be provided with a thickness e′₂ for example between 2 and 30 nm.

Next, from the structure illustrated on FIG. 6A, the gate block 132 is formed.

In the example embodiment illustrated on FIG. 6B, the insulating spacers 137 on either side of the gate block 132 are formed prior to the doping of the source and drain regions and prior to the optional doping of the extension regions.

In the example embodiment illustrated on FIG. 6C, on either side of the gate block 132 and of the spacers 137, the doped regions 125 are next formed by implanting dopants in the second semiconductor layer 120. As described previously in relation to FIG. 3, it is there also possible optionally to implement this doping by one or more inclined implantations. In a variant and as described previously in relation to FIG. 4 or 5A-5B, it is also possible to provide a reverse order of the steps for producing the spacers 137 and of doping by implantation.

Next the recrystallisation is implemented by heat treating the lower sublayer 121 while implementing an activation of the dopants of the doped regions 125 (FIG. 6D). This heat treatment is there also typically implemented so as to obtain a recrystallisation of the SPER type at a temperature preferably between 450° C. and 500° C.

This time use is made of the upper sublayer 122 as a starting region for a recrystallisation front. Having an amorphous sublayer 121 that extends over the entire surface makes it possible to have a recrystallisation front that is essentially vertical and therefore more propitious for a defect-free regeneration of the crystalline structure.

Optionally, it is possible next to implement a recrystallisation of the SPER type with an in situ doping, the doping and the recrystallisation then being implemented in this same equipment.

Advantageously, and where applicable, it is then possible to implement a removal of any non-doped surface regions.

It is possible then to implement steps as described in the previous example, in particular of growth of the semiconductor blocks 145 to form source and drain regions (FIG. 6E), and then of siliciding in order to form contacts.

As indicated previously, to obtain a structure as illustrated on FIG. 1A or a structure as illustrated on FIG. 6A, it is possible first to implement a method of assembling between a substrate 10 provided with the first semiconductor layer 12 wherein the first level of components is formed and another substrate 1 provided with the semiconductor layer 120 wherein one or more transistors of an upper level is or are provided.

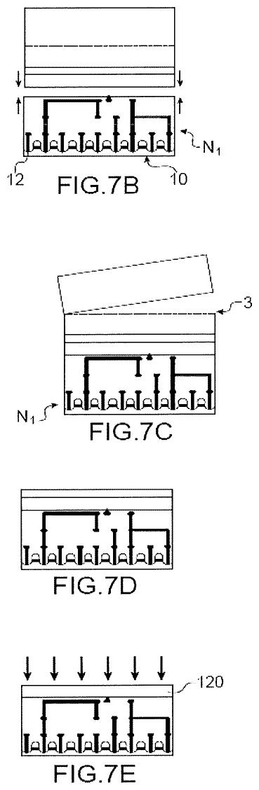

Thus, in the example embodiment illustrated on FIG. 7A, a semiconductor handle substrate 1 is provided on which the semiconductor layer 120, for example made from silicon, is disposed, and an implantation in this substrate 1 is implemented to form a weakening region 3. The implantation is implemented for example by means of H+ or helium ions.

An assembly by molecular bonding of a structure as described previously in relation to FIG. 2 and the handle substrate 1 is next implemented (FIG. 7B). The molecular bonding may for example be implemented between a layer of Si on the surface of the structure of FIG. 2 and a layer of SiO₂ covering the handle substrate 1.

FIG. 7C illustrates a subsequent step of cutting by fracturing the handle substrate 1 at the weakening region 3. An additional step of subsequent removal of a remaining thickness can then be implemented (FIG. 7D). This removal is typically implemented by planarisation (CMP).

Once the semiconductor layer 120 has been transferred onto the level N₁ of components, it is then possible to implement at least one amorphisation implantation (FIG. 7E).

Next a transistor is formed, for example in accordance with a method as described previously in relation to FIGS. 1A-1F.

Optionally, and as illustrated on FIG. 7A, the semiconductor layer 120 arranged on the handle substrate 1 can be put up against an etching stop layer 170 made from a different semiconductor material and able to be etched selectively with respect to the material of the layer 120. For example, when the semiconductor layer 120 is made from silicon, the etching stop layer 170 may be made from SiGe.

Once the transfer of the semiconductor layer 120 as implemented in FIGS. 7B-7C has been implemented, the surface semiconductor layer is thinned and this surface layer is smoothed in order to eliminate therefrom the roughness created by the fracturing step. Any residual defects liable to have been introduced into the crystal because of the implantation for producing the weakening region are eliminated and reduced.

The presence of a stop layer 170 makes it possible better to control the thickness of the layer 120 and to reduce its roughness at low temperature.

According to another possibility of implementation, it is possible to create the amorphous sublayer in the semiconductor layer 120 even before implementing the assembly by molecular bonding of a substrate 1 coated with the semiconductor layer 120 and of the substrate 10 on which a level N₁ of components is formed.

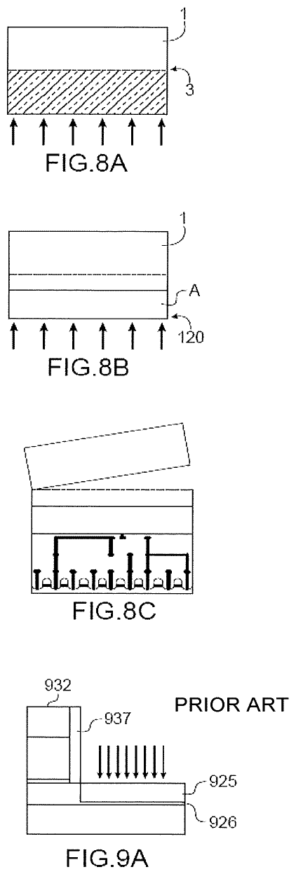

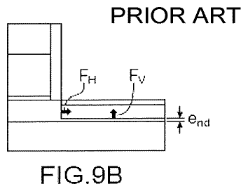

Thus, in the example embodiment illustrated on FIGS. 8A-8C, the weakening region 3 is formed.

Then (FIG. 8B) the amorphisation by implanting a sublayer of the semiconductor layer 120 is implemented.

Next the assembly by molecular bonding and then the cutting by fracturing the handle substrate 1 at the weakening region 3 are implemented (FIG. 8C).

According to a variant (not illustrated) of the method that has just been described in relation to FIGS. 8A-8C, it is also possible to implement the amorphisation of the semiconductor layer 120 on the handle substrate 1 even before producing the weakening region 3.

As with the example embodiment described previously in relation to FIGS. 7A-7E, it is possible there also, optionally, to provide an etching stop layer 170 against the semiconductor layer 120.

1. A method for producing a microelectronic device provided with a plurality of superimposed levels of electronic components, the method comprising, in this order, steps consisting in:
a) producing a structure comprising a support provided with at least one component of a first level of components, said support being surmounted by an insulating layer, the insulating layer itself being surmounted by a semiconductor layer of a second level, said semiconductor layer including at least one lower sublayer in contact with said insulating layer and an upper sublayer disposed on the lower sublayer, a first of said lower and upper sublayers being made from crystalline semiconductor material while a second of said lower and upper sublayers is made from amorphous semiconductor material, then
b) forming at least one transistor gate block on said semiconductor layer, then
c) forming, on either side of the gate block, by implantation(s) of dopants in said semiconductor layer, doped regions on either side of a semiconductor region located facing the gate block and provided for accommodating a channel of said transistor, then
d) implementing at least one heat treatment so as to implement a recrystallisation of the second amorphous sublayer while using the first crystalline sublayer as a start region of a crystalline front while implementing an activation of said dopants.

2. The method according to claim 1, wherein the step a) comprises an amorphisation implantation of a thickness of said semiconductor layer of the second level so as to form said second sublayer made from amorphous semiconductor material.

3. The method according to claim 1, said second sublayer made from amorphous semiconductor material extends over the entire surface so that the support is entirely covered by the second sublayer.

4. The method according to claim 1, wherein, at the step a), the first sublayer, made from amorphous material, is the upper sublayer, said second sublayer, made from crystalline material, being the lower sublayer.

5. The method according to claim 1, wherein, at the step a), the first sublayer, which is amorphous, is the lower sublayer, said second sublayer, which is crystalline, being the surface sublayer.

6. The method according to claim 5, wherein the formation of the structure at the step a) comprises substeps consisting in:
providing a first substrate provided with said first level of components,
bonding, on the first substrate, a second substrate provided with said semiconductor layer,
removing a portion of the second substrate while preserving the semiconductor layer bonded to the first substrate.

7. The method according to claim 6, the step a) furthermore comprises, prior to said bonding, a step of amorphisation of said semiconductor layer of the second level so as to form the second semiconductor sublayer.

8. The method according to claim 7, wherein, prior to said bonding, an implantation of the first substrate is implemented so as to create a weakening region, the amorphisation of said semiconductor layer being implemented after said creation of said weakening region.

9. The method according to claim 6, wherein an etching stop layer is arranged on the second substrate and up against said semiconductor layer, the removal of a portion of the second substrate furthermore comprising a selective etching of the etching stop layer with respect to said semiconductor layer.

10. The method according to claim 1, wherein the method comprises, after the step b):
the formation of insulating spacers on either side of the gate block,
the step c) of forming the doped regions comprising an implantation of dopants before said formation of the insulating spacers,
or,
the formation of insulating spacers on either side of the gate block, the step c) of forming the doped regions comprises an implantation of dopants implemented after said formation of the insulating spacers.

11. The method according to claim 1, furthermore comprising, after the step d): a growth of semiconductor blocks on either side of the gate block on the semiconductor layer.

12. The method according to claim 11, wherein, at the step a), the first sublayer, which is amorphous, is the lower sublayer, said second sublayer, which is crystalline, being the surface sublayer, the method furthermore comprising, after the step d) and prior to the growth of said semiconductor blocks, the removal of non-doped surface regions.

13. The method according to claim 1, wherein the recrystallisation heat treatment is implemented at a temperature below 700° C., preferentially below 550° C., and advantageously below 500° C.

14. The method according to claim 1, wherein, the component of the first level is produced in a layer of semiconductor material.
